(19) United States
(12) Patent Application Publication
(10) Pub. No.: US 2024/0136794 A1
(43) Pub. Date: Apr. 25, 2024

(54) VERTICAL CAVITY SURFACE EMITTING LASER WITH ENHANCED MODULATION BANDWIDTH

(71) Applicant: Lumentum Operations LLC, San Jose, CA (US)

(72) Inventors: Yeyu ZHU, San Jose, CA (US); Chien-Yao LU, San Jose, CA (US)

(21) Appl. No.: 18/067,296

(22) Filed: Dec. 16, 2022

Related U.S. Application Data
(60) Provisional application No. 63/380,148, filed on Oct. 19, 2022.

(51) Int. Cl. H01S 5/183

(52) U.S. Cl. CPC H01S 5/18327; H01S 5/18369

(57) ABSTRACT

In some implementations, a vertical cavity surface emitting laser (VCSEL) includes a substrate having a first side and a second side, a first mirror disposed to the first side of the substrate, a second mirror disposed to the first side of the substrate and defining a first optical cavity between the first mirror and the second mirror, an active region between the first mirror and the second mirror, and a third mirror defining a second optical cavity. The VCSEL may be configured to generate a primary optical mode and a secondary optical mode under direct modulation. The second optical cavity may be configured to resonate the secondary optical mode.

### CROSS-REFERENCE TO RELATED APPLICATION

This patent application claims priority to U.S. Provisional Patent Application No. 63/380,148, filed on Oct. 19, 2022, and entitled “BANDWIDTH ENHANCED VERTICAL CAVITY SURFACE EMITTING LASER.” The disclosure of the prior application is considered part of and is incorporated by reference into this patent application.

### TECHNICAL FIELD

The present disclosure relates generally to a vertical cavity surface emitting laser (VCSEL) and to a VCSEL with an enhanced modulation bandwidth.

### BACKGROUND

A vertical-emitting laser device, such as a VCSEL, is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, a VCSEL includes a substrate having a first side and a second side, a first mirror disposed to the first side of the substrate, a second mirror disposed to the first side of the substrate and defining a first optical cavity between the first mirror and the second mirror, an active region between the first mirror and the second mirror, and a third mirror defining a second optical cavity. The VCSEL may be configured to generate a primary optical mode and a secondary optical mode under direct modulation. The second optical cavity may be configured to resonate the secondary optical mode.

In some implementations, an emitter includes a first mirror, a second mirror defining a first optical cavity between the first mirror and the second mirror, and a third mirror defining a second optical cavity between the third mirror and the first mirror or the second mirror. The emitter may be configured to generate a primary optical mode and a secondary optical mode under direct modulation. The second optical cavity may be configured to resonate the secondary optical mode.

In some implementations, a VCSEL includes a substrate having a first side and a second side, a first mirror disposed to the first side of the substrate, a second mirror disposed to the first side of the substrate and defining a first optical cavity between the first mirror and the second mirror, an active region between the first mirror and the second mirror, and a third mirror defining a second optical cavity. The VCSEL may be configured to generate a primary optical mode and a secondary optical mode under direct modulation. The second optical cavity may be configured to cause at least one of a photon-photon resonance effect or a detuned-loading effect in an optical output of the VCSEL.

### BRIEF DESCRIPTION OF THE DRAWINGS

FIGS. 1A and 1B are diagrams illustrating a top view of an example emitter, and a cross-sectional view of the example emitter along line X-X, respectively.

FIG. 2 is a diagram illustrating an example emitter.

FIG. 3 is a diagram illustrating an example emitter.

FIG. 4 is a diagram illustrating an example emitter.

FIG. 5A shows an example plot illustrating optical modes of an emitter.

FIG. 5B shows an example plot illustrating small-signal modulation response (S21 response).

FIG. 6 shows an example plot of a reflection spectrum of a mirror of an emitter.

FIG. 7 shows an example plot of a reflection spectrum of a mirror of an emitter.

### DETAILED DESCRIPTION

The following detailed description of example implementations refers to the accompanying drawings. The same reference numbers in different drawings may identify the same or similar elements.

Directly-modulated VCSELs are suitable for numerous applications, such as applications in data centers for data communications and in three-dimensional (3D) sensing for light detection and ranging (LIDAR). Generally, a large modulation bandwidth for directly-modulated VCSELs is desirable. However, current modulation bandwidths for directly modulated VCSELs may be less than 30 gigahertz (GHz).

Some implementations described herein provide a directly-modulated emitter device (e.g., a VCSEL) that utilizes a photon-photon resonance (PPR) effect and/or a detuned-loading effect (e.g., separately or at the same time) to improve a modulation bandwidth of the emitter device. In some implementations, the emitter device may include a substrate having a first side (e.g., a top surface) and a second side (e.g., a bottom surface). A first mirror and a second mirror of the emitter device, defining a first optical cavity of the emitter device, may be disposed to the first side of the substrate. A third mirror of the emitter device may define a second optical cavity with the first mirror or the second mirror. For example, the third mirror may be disposed to the second side of the substrate. However, other configurations may be employed without departing from the scope of the present disclosure.

Direct modulation of the emitter device may generate a primary optical mode and a secondary optical mode in a vicinity (i.e., in a frequency range) of the primary optical mode. In some implementations, the second optical cavity may provide feedback (e.g., passive feedback) and facilitate excitation of the secondary optical mode to cause a resonant enhancement of a modulation sideband near the primary optical mode using the PPR effect. In this way, the PPR effect may provide enhancement of the modulation bandwidth of the emitter device.

Furthermore, the second optical cavity may provide a reflection spectrum associated with different reflectivity when the emitter device is biased at different current settings (e.g., associated with an on state of the emitter device and an off state of the emitter device). For example, a wavelength of an optical output of the emitter device may shift (e.g., a wavelength chirp) as the emitter device is modulated from an on state to an off state. The shift may move the wavelength away from a peak reflectivity of the second optical cavity, thereby decreasing the feedback from the second optical cavity. Thus, due to the detuned loading effect, the optical output of the emitter device may decrease faster than the optical output would decrease by a change in drive current alone, thereby providing a modulation bandwidth enhancement for the emitter device. For example, the shift may effectively enhance differential gain, thereby improving the modulation speed of the emitter device. Moreover, a linewidth enhancement factor may also be reduced due to the detuned loading effect, thereby improving a relative intensity noise (RIN) performance of the emitter device.

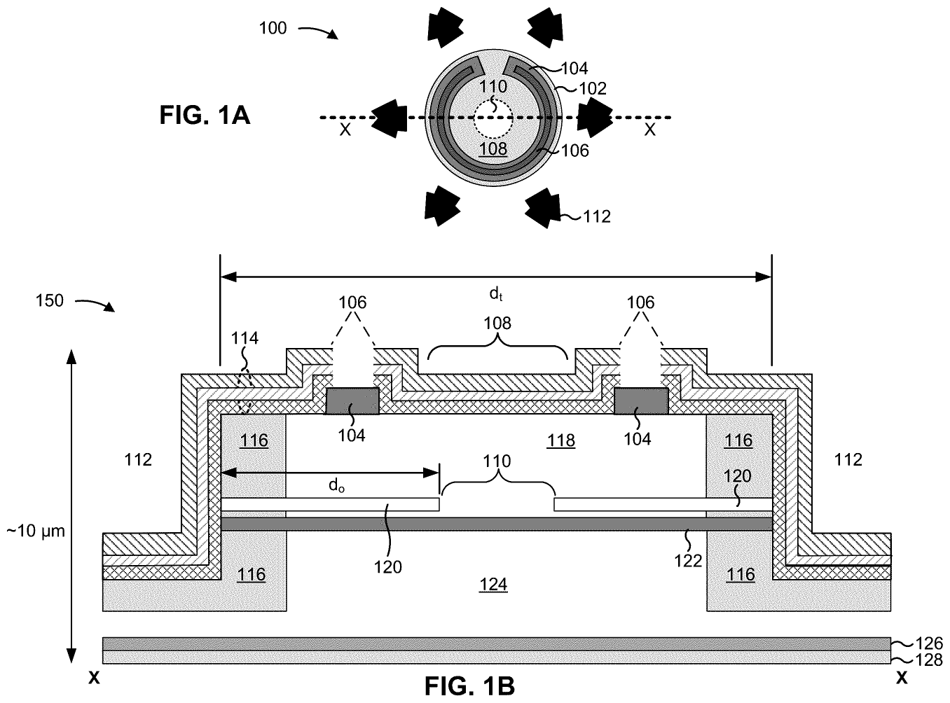

FIGS. 1A and 1B are diagrams illustrating a top-view of an example of a conventional emitter 100 and a cross-sectional view 150 of the example emitter 100 along line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g., a dielectric layer, a passivation layer, or a dielectric mirror composed of multiple layers) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium gray area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112 (e.g., of the same size or of different sizes), in practice, other configurations may be used, such as a compact emitter that includes five trenches 112, seven trenches 112, or another quantity of trenches. In some implementations, trenches 112 may encircle emitter 100 to form a mesa structure dₜ (shown in FIG. 1B). As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are contemplated. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 micrometers (μm).

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as dₒ in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer, and which may act as an additional DBR. For example, protective layer 114 may include one or more sub-layers (e.g., a dielectric passivation layer and/or a mirror layer, a SiO₂ layer, a Si₃N₄ layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor, may provide a non-rectifying electrical junction, and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B are provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100, and any layer may comprise more than one layer.

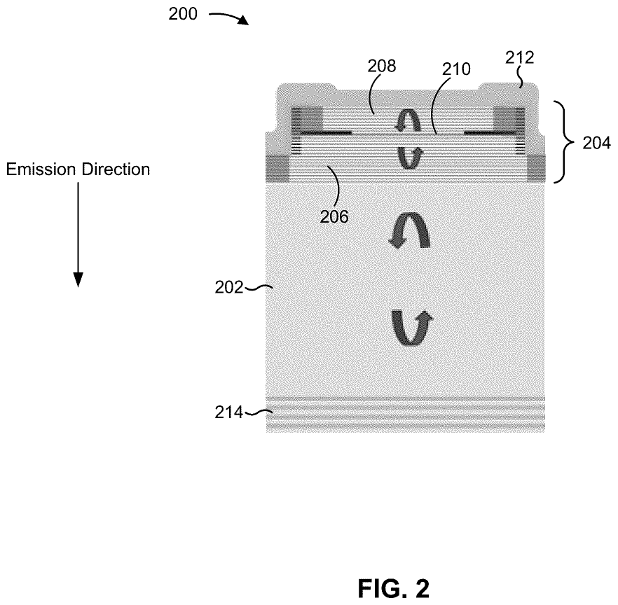

FIG. 2 is a diagram illustrating an example emitter 200. The emitter 200 may be a VCSEL. The emitter 200 may be in a bottom-emitting configuration, as shown in FIG. 2.

The emitter 200 may be configured for direct modulation. For example, an apparatus or a system that includes the emitter 200 may provide direct modulation of the emitter 200. The emitter 200 may be configured to generate a primary optical mode and a secondary optical mode under direct modulation.

As shown in FIG. 2, the emitter 200 may include a substrate 202, in a similar manner as described in connection with FIGS. 1A-1B. The substrate 202 may have a first side (e.g., top surface) and a second side (e.g., a bottom surface) opposite the first side, which define a thickness of the substrate 202. In some implementations, the thickness of the substrate 202 may be about 100 μm. A set of epitaxial layers 204, similar to those described in connection with FIGS. 1A-1B, may be disposed on (e.g., formed on) the first side of the substrate 202. The set of epitaxial layers 204 may include a first mirror 206 (e.g., a first DBR) and a second mirror 208 (e.g., a second DBR). In other words, the first mirror 206 may be disposed to the first side of the substrate 202 (i.e., disposed on the first side of the substrate 202) and the second mirror 208 may be disposed to the first side of the substrate 202 (i.e., disposed on the first side of the substrate 202). A first optical cavity (e.g., an optical resonator) may be defined between the first mirror 206 and the second mirror 208. The set of epitaxial layers 204 may include an active region 210 (e.g., a quantum well) between the first mirror 206 and the second mirror 208 (e.g., in the first optical cavity). That is, the first optical cavity may be active. The emitter 200 may include an electrical contact layer 212 (e.g., an ohmic metal layer) electrically connected to the set of epitaxial layers 204.

The emitter 200 may include a third mirror 214. In some implementations, the third mirror 214 may be disposed to the second side of the substrate 202 (e.g., disposed on the second side of the substrate 202), as shown. In some implementations, the third mirror 214 may be disposed to the first side of the substrate 202 (e.g., the third mirror 214 may be in the set of epitaxial layers 204) between the substrate 202 and the first mirror 206. Here, a semiconductor layer (not shown), similar to the substrate 202, may be disposed between the third mirror 214 and the first mirror 206. In some implementations, the third mirror 214 may be disposed to the first side of the substrate 202 (e.g., the third mirror 214 may be in the set of epitaxial layers 204) between the first mirror 206 and the second mirror 208. In some implementations, the third mirror 214 may be disposed to the first side of the substrate 202 (e.g., the third mirror 214 may be in the set of epitaxial layers 204), and the second mirror 208 may be between the first mirror 206 and the third mirror 214.

The third mirror may define a second optical cavity (e.g., an optical resonator) between the third mirror 214 and the first mirror 206 or the second mirror 208. For example, the second optical cavity may be between the third mirror 214 and the first mirror 206. As another example, the second optical cavity may be between the third mirror 214 and the second mirror 208. In some implementations (e.g., when the third mirror 214 is disposed to the second side of the substrate 202), the substrate 202 may be in the second optical cavity. The second optical cavity may be inactive (e.g., there may be no gain medium in the second optical cavity). In some implementations, the second optical cavity may be an optical cavity that is external to a main structure of the emitter 200, defined by the set of epitaxial layers 204, and that is integrated into the main structure.

In some implementations, the third mirror 214 may include a plurality of dielectric layers (e.g., dielectric films) having alternating refractive indexes. For example, the dielectric layers may include interleaved higher refractive index layers and lower refractive index layers (e.g., a difference between the higher refractive index and the lower refractive index may be from about 0.1 to about 2). In some implementations, the third mirror 214 may include a DBR, as described herein. In some implementations, the third mirror 214 may be configured to provide an optical power reflection of less than 10%, such as about 5% or less or about 3% or less. In this way, an output power of the emitter 200 may not be significantly diminished.

In some implementations, the second optical cavity may be configured to resonate the secondary optical mode that may be generated by the emitter 200 under direct modulation. For example, the second optical cavity may be tuned (e.g., the third mirror 214 may be tuned) to resonate at a frequency of the secondary optical mode. In some implementations, the emitter 200 may be configured for thermal tuning of the first optical cavity and/or the second optical cavity (e.g., for thermal tuning of the first mirror 206, the second mirror 208, and/or the third mirror 214). For example, the emitter 200 may include one or more heating elements for thermal tuning. In some implementations, the first optical cavity may be tuned to align the primary optical mode and the secondary optical mode (e.g., the primary optical mode may be biased at a longer-wavelength side of the first mirror 206 and/or the second mirror 208).

The second optical cavity may be configured to cause at least one of the PPR effect or the detuned-loading effect in an optical output of the emitter 200 (e.g., to cause both of the PPR effect and the detuned-loading effect in an optical output of the emitter 200), as described herein. For example, the second optical cavity may be configured to cause the PPR effect and/or the detuned-loading effect under direct modulation of the emitter 200. The second optical cavity, by resonating the secondary optical mode, may provide PPR, thereby improving a response time and a modulation bandwidth of the emitter 200. Moreover, modulation of the emitter 200 from an on state to an off state may cause a wavelength shift away from a peak reflectivity of the second optical cavity, thereby quickly diminishing feedback from the second optical cavity and improving a modulation bandwidth of the emitter 200.

As indicated above, FIG. 2 is provided as an example. Other examples may differ from what is described with regard to FIG. 2.

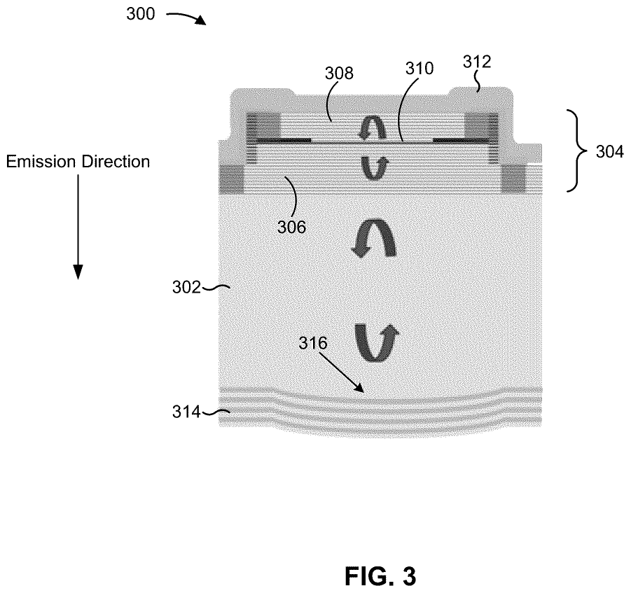

FIG. 3 is a diagram illustrating an example emitter 300. The emitter 300 may be a VCSEL. The emitter 300 may be in a bottom-emitting configuration, as shown in FIG. 3. The emitter 300 may include a substrate 302, having a first side (e.g., a top surface) and a second side (e.g., a bottom surface) opposite the first side, and a set of epitaxial layers 304, disposed on the first side of the substrate 302, that includes a first mirror 306, a second mirror 308, and an active region 310 between the first mirror 306 and the second mirror 308, in a similar manner as described in connection with FIG. 2. The emitter 300 may include an electrical contact layer 312 electrically connected to the set of epitaxial layers 304, in a similar manner as described in connection with FIG. 2.

As shown, an optical element 316 may be integrated into the second side (e.g., the bottom surface) of the substrate 302. For example, the optical element 316 may be a lens. The emitter 300 may include a third mirror 314 disposed to the second side of the substrate 302 (i.e., disposed on the bottom surface of the substrate 302); however, other configurations of the third mirror 314 may be utilized, in a similar manner as described in connection with FIG. 2. For example, the third mirror 314 may be disposed on the optical element 316. Thus, the third mirror 314 may correspond in shape to the second side of the substrate 302 that integrates the optical element 316. For example, the third mirror 314 may be convex, as shown, concave, or another non-planar shape.

As indicated above, FIG. 3 is provided as an example. Other examples may differ from what is described with regard to FIG. 3.

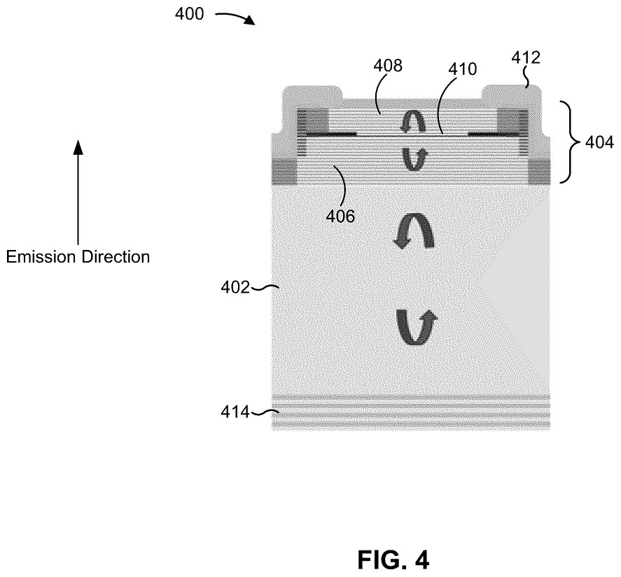

FIG. 4 is a diagram illustrating an example emitter 400. The emitter 400 may be a VCSEL. The emitter 400 may be in a top-emitting configuration, as shown in FIG. 4. The emitter 400 may include a substrate 402, having a first side (e.g., a top surface) and a second side (e.g., a bottom surface) opposite the first side, and a set of epitaxial layers 404, disposed on the first side of the substrate 402, that includes a first mirror 406, a second mirror 408, and an active region 410 between the first mirror 406 and the second mirror 408, in a similar manner as described in connection with FIG. 2. The emitter 400 may include an electrical contact layer 412 electrically connected to the set of epitaxial layers 404, in a similar manner as described in connection with FIG. 2. As shown in FIG. 4, the electrical contact layer 412 may be in a ring shape or a partial-ring shape to facilitate top emission of the emitter 400. The emitter 400 may include a third mirror 414 disposed to the second side of the substrate 402 (i.e., disposed on the bottom surface of the substrate 402); however, other configurations of the third mirror 414 may be utilized, in a similar manner as described in connection with FIG. 2.

As indicated above, FIG. 4 is provided as an example. Other examples may differ from what is described with regard to FIG. 4.

The emitters described herein (e.g., the emitter 200, 300, or 400) may include an oxide confined emitter device, an implant-only emitter device, a mesa type emitter device, a top-emitting emitter device, a bottom-emitting emitter device, a multi-junction emitter device (e.g., an emitter with multiple active regions 210 included within epitaxial layers 204), and/or another emitter device. The emitters may be configured to emit light associated with one or more wavelength ranges such as 800 nanometers (nm) to 1550 nm, and/or may utilize different material systems, such as those that include a GaAs substrate or an InP substrate. The emitters may include emitters of any number, any sizes, and/or arranged in any array shape, among other examples. The emitters may employ a circular shape oxidation aperture, or another shape oxidation aperture, such as oval, rectangular, or the like. As described herein, the emitters may be VCSELs.

Some implementations provide a method of fabricating the emitter 200, 300, or 400. In some implementations, the method may include forming a first mirror (e.g., first mirror 206, 306, or 406) on a first side of a substrate (e.g., substrate 202, 302, or 402). The method may include forming an active region (e.g., active region 210, 310, or 410) on the first mirror. The method may include forming a second mirror (e.g., second mirror 208, 308, or 408) on the active region. The method may include forming a third mirror (e.g., third mirror 214, 314, or 414) on a second side of the substrate or on the first side of the substrate, as described herein.

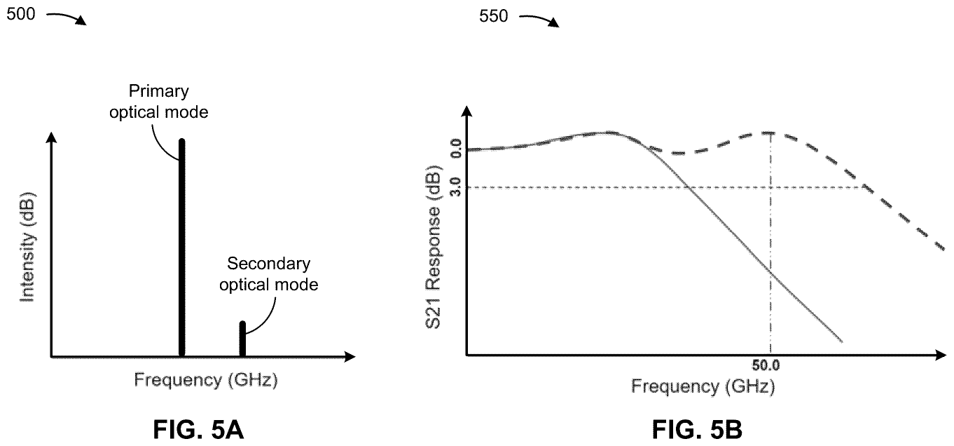

FIG. 5A shows an example plot 500 illustrating optical modes of an emitter. The emitter may have a first optical cavity and a second optical cavity (e.g., the emitter 200, 300, or 400), as described herein. As shown, the emitter may facilitate excitation of a primary optical mode and a secondary optical mode, using the second optical cavity, under direct modulation. The secondary optical mode may have a frequency separation from the primary optical mode. For example, the primary optical mode and the secondary optical mode may be separated in frequency by about 50 GHz. FIG. 5B shows an example plot 550 illustrating small-signal modulation response (S21 response). In particular, plot 550 shows the S21 response (solid line) of an emitter (e.g., a VCSEL) that includes a single optical cavity, and the S21 response (dashed line) of an emitter having a first optical cavity and a second optical cavity (e.g., the emitter 200, 300, or 400), as described herein. As shown, the emitter having the first optical cavity and the second optical cavity may exhibit a peak in S21 response (e.g., around 50 GHz) that is due to the PPR effect. Thus, the PPR effect may increase a modulation bandwidth of the emitter beyond that which is achievable by the emitter having the single optical cavity.

As indicated above, FIGS. 5A-5B are provided as examples. Other examples may differ from what is described with regard to FIGS. 5A-5B.

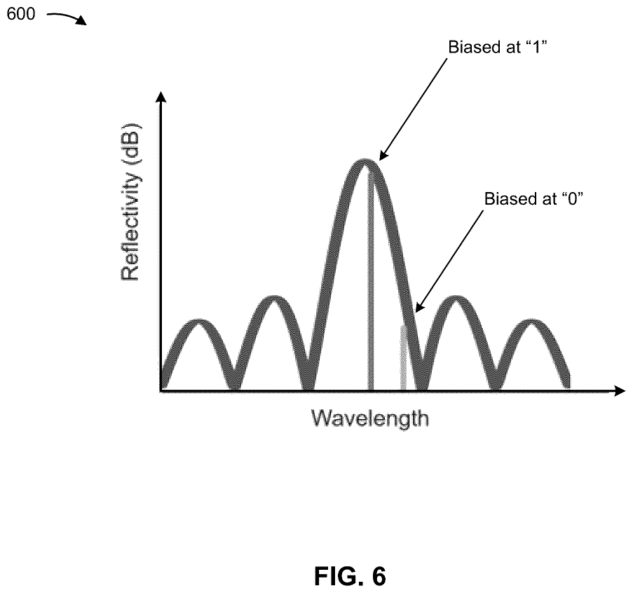

FIG. 6 shows an example plot 600 of a reflection spectrum of a mirror (e.g., a reflector) of an emitter. The emitter may have a first optical cavity and a second optical cavity (e.g., the emitter 200, 300, or 400), as described herein. When the emitter is biased to a first current setting associated with an on state (shown as biased at “1”), a primary optical mode of the emitter may be at a first wavelength. As shown, transitioning from the on state to biasing the emitter to a second current setting associated with an off state (shown as biased at “0”) may cause a shift in the wavelength of the primary optical mode to a second wavelength. As further shown, the mirror's reflectivity of the primary optical mode may be different when the emitter is biased at different current settings. For example, the mirror's optical power reflection of the primary optical mode at the first wavelength may be greater than the mirror's optical power reflection of the primary optical mode at the second wavelength. Thus, the detuned-loading effect associated with the wavelength shift may enhance differential gain, thereby improving the modulation speed of the emitter.

As indicated above, FIG. 6 is provided as an example. Other examples may differ from what is described with regard to FIG. 6.

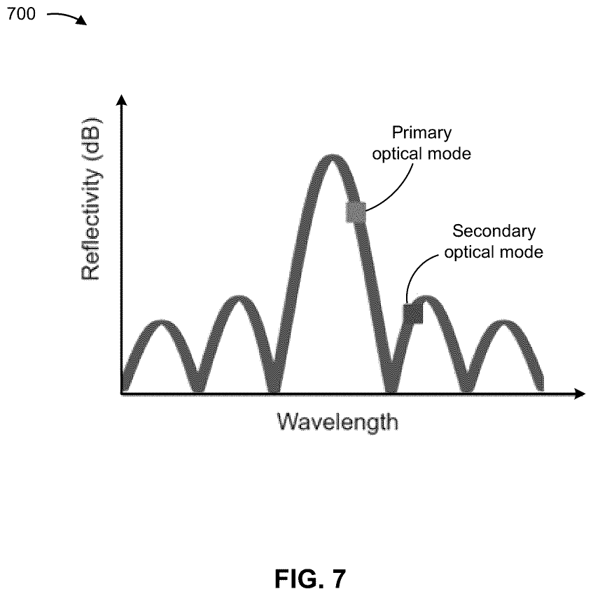

FIG. 7 shows an example plot 700 of a reflection spectrum of a mirror (e.g., a reflector) of an emitter. The emitter may have a first optical cavity and a second optical cavity (e.g., the emitter 200, 300, or 400), as described herein. As shown, an optical power reflection of the mirror in connection with a primary optical mode of a first wavelength may be different from an optical power reflection of the mirror in connection with a secondary optical mode of a second wavelength. Through the use of thermal tuning, the primary optical mode may be biased at a longer-wavelength side of the mirror. In addition, through the use of thermal tuning, the secondary optical mode (e.g., in a modulation sideband), used for achieving the PPR effect as described herein, may be obtained. In particular, the PPR effect utilizes the presence of the secondary optical mode in the vicinity of the primary optical mode.

As indicated above, FIG. 7 is provided as an example. Other examples may differ from what is described with regard to FIG. 7.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL), comprising:
a substrate having a first side and a second side;
a first mirror disposed to the first side of the substrate;
a second mirror disposed to the first side of the substrate and defining a first optical cavity between the first mirror and the second mirror;
an active region between the first mirror and the second mirror; and
a third mirror defining a second optical cavity,
wherein the VCSEL is to generate a primary optical mode and a secondary optical mode under direct modulation, and
wherein the second optical cavity is configured to resonate the secondary optical mode.

2. The VCSEL of claim 1, wherein the third mirror is disposed to the second side of the substrate.

3. The VCSEL of claim 1, wherein the third mirror is disposed to the first side of the substrate between the substrate and the first mirror.

4. The VCSEL of claim 1, wherein the third mirror is disposed to the first side of the substrate between the first mirror and the second mirror.

5. The VCSEL of claim 1, wherein the third mirror is disposed to the first side of the substrate, and
wherein the second mirror is between the first mirror and the third mirror.

6. The VCSEL of claim 1, wherein the second optical cavity is configured to cause at least one of a photon-photon resonance effect or a detuned-loading effect in an optical output of the VCSEL.

7. The VCSEL of claim 1, wherein an optical element is integrated into the second side of the substrate.

8. The VCSEL of claim 7, wherein the third mirror is disposed on the optical element.

9. An emitter, comprising:
a first mirror;
a second mirror defining a first optical cavity between the first mirror and the second mirror; and
a third mirror defining a second optical cavity between the third mirror and the first mirror or the second mirror,
wherein the emitter is to generate a primary optical mode and a secondary optical mode under direct modulation, and
wherein the second optical cavity is configured to resonate the secondary optical mode.

10. The emitter of claim 9, wherein the first mirror and the second mirror are disposed to a first side of a substrate, and
wherein the third mirror is disposed to a second side of the substrate.

11. The emitter of claim 9, wherein the third mirror is configured to provide an optical power reflection of less than 10%.

12. The emitter of claim 9, wherein the second optical cavity is configured to cause at least one of a photon-photon resonance effect or a detuned-loading effect in an optical output of the emitter.

13. The emitter of claim 9, wherein the third mirror includes a plurality of dielectric layers having alternating refractive indexes.

14. The emitter of claim 9, wherein the third mirror includes a distributed Bragg reflector.

15. A vertical cavity surface emitting laser (VCSEL), comprising:
a substrate having a first side and a second side;
a first mirror disposed to the first side of the substrate;
a second mirror disposed to the first side of the substrate and defining a first optical cavity between the first mirror and the second mirror;
an active region between the first mirror and the second mirror; and
a third mirror defining a second optical cavity,
wherein the VCSEL is to generate a primary optical mode and a secondary optical mode under direct modulation, and
wherein the second optical cavity is configured to cause at least one of a photon-photon resonance effect or a detuned-loading effect in an optical output of the VCSEL.

16. The VCSEL of claim 15, wherein the third mirror is disposed to the second side of the substrate.

17. The VCSEL of claim 15, wherein the second optical cavity is between the third mirror and the first mirror.

18. The VCSEL of claim 15, wherein the second optical cavity is between the third mirror and the second mirror.

19. The VCSEL of claim 15, wherein the second optical cavity is tuned to resonate at a frequency of the secondary optical mode.

20. The VCSEL of claim 15, wherein the first optical cavity is tuned to align the primary optical mode with the secondary optical mode.
